(19) United States
(12) Patent Application Publication
(10) Pub. No.: US 2011/0115955 A1
(43) Pub. Date: May 19, 2011

(54) SOLID-STATE IMAGE DEVICE AND METHOD OF MANUFACTURING THE SAME

(75) Inventors: Tomoo Okutani, Hyogo (JP); Kazuo Fujiwara, Toyama (JP); Hitomi Fujiwara, Toyama (JP)

(73) Assignee: PANASONIC CORPORATION, Osaka (JP)

(21) Appl. No.: 13/006,936

(22) Filed: Jan. 14, 2011

Related U.S. Application Data
(63) Continuation of application No. PCT/JP2009/001730, filed on Apr. 15, 2009.

(30) Foreign Application Priority Data
Jul. 14, 2008 (JP) 2008-182127

(51) Int. Cl. H04N 5/335; H01L 31/0224

(52) U.S. Cl. 348/300; 348/294; 348/311; 348/308; 438/98; 348/E05.091; 257/E31.124

(57) ABSTRACT

An object of the present invention is to provide a solid-state image device that can effectively dissipate heat. In order to attain the object, the solid-state image device of the present invention includes non-through heat dissipation portions (7) provided on a semiconductor substrate (2). The non-through heat dissipation portion (7) is made up of a non-through hole and a metal embedded in the non-through hole. The non-through hole has one open end on one of the surfaces of the semiconductor substrate (2), extends from the one surface toward the other surface of the semiconductor substrate (2), and has the other end between the surfaces of the semiconductor substrate (2). The non-through heat dissipation portions (7) act as heat dissipation paths.

### FIELD OF THE INVENTION

The present invention relates to a solid-state image device and a method of manufacturing the same.

### BACKGROUND OF THE INVENTION

Generally, solid-state image devices of charge-coupled device (CCD) type and metal-oxide-semiconductor (MOS) type are used as image pickup devices of a video camera, a digital still camera, and so on.

In recent years, electronic equipment such as digital still cameras and portable equipment, in which solid-state image devices are mounted, has been reduced in size and thus smaller solid-state image devices have been demanded. While semiconductor chips including solid-state image elements have been reduced in size, technological innovations have been accelerated for size reduction of the structures of solid-state image devices.

A typical solid-state image device is configured such that a semiconductor chip is fixed in a container having an opening top, the electrodes of the fixed semiconductor chip and leads provided beforehand in the container are connected to each other via wires, and a light-transmissive member such as a glass plate is fixed on the top of the container. On the semiconductor substrate of the semiconductor chip, a solid-state image element is formed that includes a light receiving part.

Recently techniques of manufacturing wafer level chips called wafer level chip size packages (WLCSPs) have been developed and solid-state image devices at a wafer level have been also developed in response to the techniques (e.g., see Japanese Patent Laid-Open No. 2001-351997). In a WLCSP, power is supplied to a chip from the backside through electrodes penetrating a semiconductor substrate.

Referring to FIGS. 17 and 18, the following will describe the configuration of a solid-state image device at a wafer level according to the related art. The solid-state image device is a CCD solid-state image device. FIG. 17 is a sectional view showing the CCD solid-state image device at the wafer level according to the related art. FIG. 18 is a top view showing the CCD solid-state image device at the wafer level according to the related art.

In a solid-state image device 101, a light receiving part 103 and multiple wiring layers 104 are formed on the top surface of a semiconductor substrate 102. The wiring layers 104 are placed around the light receiving part 103 and are connected to the light receiving part 103. In order to improve light collection efficiency, lenses 105 are provided on the light receiving part 103. On the semiconductor substrate 102, multiple penetration electrodes 106 are formed. The penetration electrodes 106 penetrate the semiconductor substrate 102 from the underside to the top surface of the semiconductor substrate 102 and are connected to the wiring layers 104. As shown in FIG. 18, each of the wiring layers 104 includes a region 107 in which the penetration electrode 106 is formed.

On the top surface of the semiconductor substrate 102, elements (not shown) such as a horizontal CCD and an output amplifier are formed which constitute a CCD solid-stage image element. Further, a light transmissive member (not shown) is provided above the semiconductor substrate 102. In the case of a MOS solid-state image device, elements constituting a MOS solid-stage image element, e.g., circuits such as various scanning circuits, an output circuit, and a logic circuit are formed on the top surface of a semiconductor substrate in addition to a light receiving part and wiring layers.

Referring to FIG. 19, the following will describe a method of forming the penetration electrodes in the solid-state image device at the wafer level according to the related art. The penetration electrodes are formed after the solid-state image element including the light receiving part is formed on the top surface of the semiconductor substrate. In FIG. 19, the same elements as in FIGS. 17 and 18 are indicated by the same reference numerals and the specific explanation thereof is omitted.

First, a photoresist 108 is applied to the underside of the semiconductor substrate 102. Next, the photoresist 108 is patterned with an opening diameter of d1 by photolithography. Next, dry etching is performed from the underside of the semiconductor substrate 102 to form through holes 109 that penetrate the semiconductor substrate 102 from the underside to the top surface of the semiconductor substrate 102 and reach the wiring layer 104. At this point, the through holes 109 are tapered down toward the top surface of the semiconductor substrate 102 in longitudinal section because of the properties of dry etching.

Next, the patterned photoresist 108 is removed and then an insulating film 110 is formed from the underside of the semiconductor substrate 102 by, e.g., chemical vapor deposition (CVD). This processing forms the insulating film 110 on the inner surfaces of the through holes 109 and the exposed surfaces of the wiring layers 104 in the through holes 109.

After that, the insulating film 110 is removed from the exposed surfaces of the wiring layers 104 in the through holes 109. Finally, a metal 111 is embedded in the through holes 109 by, e.g., electroplating.

The solid-state image device at the wafer level can be structurally reduced in size. Since the accuracy of cutting of a semiconductor wafer is equivalent to the accuracy of outer dimensions of the solid-state image device, it is possible to improve the accuracy of positioning for installing the solid-state image device in equipment.

In the solid-state image device at the wafer level, the penetration electrodes penetrating the semiconductor substrate are provided for power supply from the outside. In other words, the penetration electrodes act as power feed lines. Further, the penetration electrodes act as dissipation paths for releasing heat from the solid-state image device to the outside. Thus, for example, when the solid-state image device is mounted on a printed circuit board via a mounting member, heat from the solid-state image element formed on the semiconductor substrate is mainly released from the metal of the penetration electrodes to the printed circuit board through the mounting member.

As has been discussed, in the solid-state image device at the wafer level according to the related art, the penetration electrodes act as main dissipation paths. However, the penetration electrodes for power supply are formed directly under the wiring layers placed around the light receiving part and thus the solid-state image device at the wafer level according to the related art cannot efficiently dissipate heat from beneath the light receiving part in which heat directly causes image degradation. Further, in the case of a CCD solid-state image device, heat cannot be efficiently dissipated from beneath a horizontal CCD and an output amplifier that are the main heat sources of the solid-state image device. Moreover, in the case of a MOS solid-state image device, heat cannot be efficiently dissipated from beneath a logic circuit that is the main heat source of the solid-state image device. The logic circuit of the MOS solid-state image device includes a timing generator and an A/D converter.

In recent years, smaller and faster solid-state image devices have been increasingly demanded and image characteristics have been seriously degraded such that problems such as shading, white spots, and dark current occur due to high temperatures in solid-state image devices.

The present invention has been devised in view of the problems of the related art. An object of the present invention is to provide a solid-state image device and a method of manufacturing the same by which heat dissipation can be improved in the solid-state image device fed with power from the outside through penetration electrodes provided on a semiconductor substrate, and thus image degradation caused by heat can be prevented.

### DISCLOSURE OF THE INVENTION

In order to attain the object, a first solid-state image device of the present invention includes: a semiconductor substrate having a first surface and a second surface opposed to the first surface; a light receiving part formed on the first surface; front-side wires formed around the light receiving part on the first surface; penetration electrodes that penetrate the semiconductor substrate from the second surface to the first surface and are connected to the front-side wires; and non-through heat dissipation portions each of which includes a non-through hole and a metal embedded in the non-through hole, the non-through hole having one open end on the second surface, extending from the second surface toward the first surface, and having the other end between the first surface and the second surface.

A second solid-state image device of the present invention, in the first solid-state image device of the present invention, wherein the end of the non-through heat dissipation portion on the second surface is smaller in diameter than the end of the penetration electrode on the second surface.

A third solid-state image device of the present invention, in the first solid-state image device of the present invention, wherein the non-through heat dissipation portions are not so deep as to reach a well formed on the semiconductor substrate.

A fourth solid-state image device of the present invention, in the first solid-state image device of the present invention, further includes a CCD solid-state image element formed on the first surface.

A fifth solid-state image device of the present invention, in the fourth solid-state image device of the present invention, wherein the ends of the non-through heat dissipation portions on the first surface are disposed directly under one of the light receiving part, the output amplifier, and the horizontal CCD of the CCD solid-state image element formed on the first surface.

A sixth solid-state image device of the present invention, in the first solid-state image device of the present invention, further includes a MOS solid-state image element formed on the first surface.

A seventh solid-state image device of the present invention, in the sixth solid-state image device of the present invention, wherein the ends of the non-through heat dissipation portions on the first surface are disposed directly under one of the light receiving part and the logic circuit of the MOS solid-state image element formed on the first surface.

An eighth solid-state image device of the present invention, in the first solid-state image device of the present invention, wherein the non-through heat dissipation portions are tapered down from the second surface toward the first surface or have a constant diameter.

A ninth solid-state image device of the present invention, in the first solid-state image device of the present invention, further includes external connection electrodes on the second surface, the external connection electrodes being provided directly under the ends of the non-through heat dissipation portions on the second surface.

A tenth solid-state image device of the present invention, in the ninth solid-state image device of the present invention, further includes backside wires connected to the ends of the non-through heat dissipation portions on the second surface, wherein the external connection electrodes are connected to the non-through heat dissipation portions via the backside wires.

An eleventh solid-state image device of the present invention, in the first solid-state image device of the present invention, further includes: backside wires connected to the ends of the non-through heat dissipation portions on the second surface; and external connection electrodes connected to the backside wires, wherein the external connection electrodes are separated from positions directly under the ends of the non-through heat dissipation portions on the second surface.

A first method of manufacturing a solid-state image device of the present invention, when penetration electrodes are formed on a semiconductor substrate that has a first surface and a second surface opposed to the first surface and includes wires on the first surface, the method including the steps of: forming a pattern on the second surface such that openings are formed on penetration electrode formation regions and non-through heat dissipation portion formation regions and the opening formed on the penetration electrode formation region and the opening formed on the non-through heat dissipation portion formation region have different opening diameters from each other; forming through holes in the penetration electrode formation regions and non-through holes in the non-through heat dissipation portion formation regions, the through holes penetrating the semiconductor substrate from the second surface to the first surface and reaching the wires, the non-through holes having one open ends on the second surface, extending from the second surface toward the first surface, and having the other ends between the first surface and the second surface; removing the pattern; forming an insulating film on the inner surfaces of the through holes, the exposed surfaces of the wires in the through holes, and the inner surfaces of the non-through holes; removing the insulating film on the exposed surfaces of the wires in the through holes; and embedding a metal in the through holes and the non-through holes.

A second method of manufacturing a solid-state image device of the present invention, when penetration electrodes are formed on a semiconductor substrate that has a first surface and a second surface opposed to the first surface and includes wires on the first surface, the method including the steps of: forming a pattern on the second surface such that openings are formed on penetration electrode formation regions and non-through heat dissipation portion formation regions and the opening formed on the penetration electrode formation region has a different depth from the opening formed on the non-through heat dissipation portion formation region; forming through holes in the penetration electrode formation regions and non-through holes in the non-through heat dissipation portion formation regions, the through holes penetrating the semiconductor substrate from the second surface to the first surface and reaching the wires, the non-through holes having one open ends on the second surface, extending from the second surface toward the first surface, and having the other ends between the first surface and the second surface; removing the pattern; forming an insulating film on the inner surfaces of the through holes, the exposed surfaces of the wires in the through holes, and the inner surfaces of the non-through holes; removing the insulating film on the exposed surfaces of the wires in the through holes; and embedding a metal in the through holes and the non-through holes.

A preferred embodiment of the present invention can improve the heat dissipation of a solid-state image device and thus suppress the degradation of image characteristics, e.g., shading, white spots, and dark current that occur due to high temperatures in the solid-state image device. It is therefore possible to provide a solid-state image device that can simultaneously achieve size reduction, high-speed driving, and suppressed image degradation. Consequently, the solid-state image device and the method of manufacturing the same are useful for a solid-state image device used for equipment such as portable equipment, a digital still camera, and a video camera because such equipment requires size reduction and suppression of image degradation caused by heat generated in size reduction.

### BRIEF DESCRIPTION OF THE DRAWINGS

FIG. 1 is a sectional view showing a structural example of a solid-state image device according to an embodiment of the present invention;

FIG. 2 is a sectional view showing an example of the relationship between the end diameters of a penetration electrode and a non-through heat dissipation portion in the solid-state image device according to the embodiment of the present invention;

FIG. 3 is a sectional view showing an example of the positional relationship between the non-through heat dissipation portions and a well in the solid-state image device according to the embodiment of the present invention;

FIG. 4 is a top view showing an example of a CCD solid-state image device according to the embodiment of the present invention;

FIG. 5 is a top view showing another example of the CCD solid-state image device according to the embodiment of the present invention;

FIG. 6 is a top view showing still another example of the CCD solid-state image device according to the embodiment of the present invention;

FIG. 7 is a top view showing an example of a MOS solid-state image device according the embodiment of the present invention;

FIG. 8 is a top view showing another example of the MOS solid-state image device according the embodiment of the present invention;

FIG. 9 is a sectional view showing an example of the shapes of the non-through heat dissipation portions in the solid-state image device according the embodiment of the present invention;

FIG. 10 is a sectional view showing an example of the position of the non-through heat dissipation portion formed in the solid-state image device according the embodiment of the present invention;

FIG. 11 is a top view showing the example of the position of the non-through heat dissipation portion formed in the solid-state image device according the embodiment of the present invention;

FIG. 12 is a sectional view showing another example of the position of the non-through heat dissipation portion formed in the solid-state image device according to the embodiment of the present invention;

FIG. 13 is a top view showing the other example of the position of the non-through heat dissipation portion formed in the solid-state image device according to the embodiment of the present invention;

FIG. 14 is a process sectional view showing an example of a method of manufacturing the solid-state image device according to the embodiment of the present invention;

FIG. 15 is a sectional view showing the relationship between the opening diameter of a non-through hole and the taper angle of etching in the method of manufacturing the solid-state image device according to the embodiment of the present invention;

FIG. 16 is a process sectional view showing another example of the method of manufacturing the solid-state image device according to the embodiment of the present invention;

FIG. 17 is a sectional view showing a CCD solid-state image device at a wafer level according to the related art;

FIG. 18 is a top view showing the CCD solid-state image device at the wafer level according to the related art; and

FIG. 19 is a process sectional view for explaining a method of forming penetration electrodes in the solid-state image device at the wafer level according to the related art.

### DESCRIPTION OF THE EMBODIMENT

The following will describe an embodiment of a solid-state image device of the present invention and a method of manufacturing the same in accordance with the accompanying drawings. In the drawings, the same elements as in the foregoing explanation are indicated by the same reference numerals and the explanation thereof is omitted.

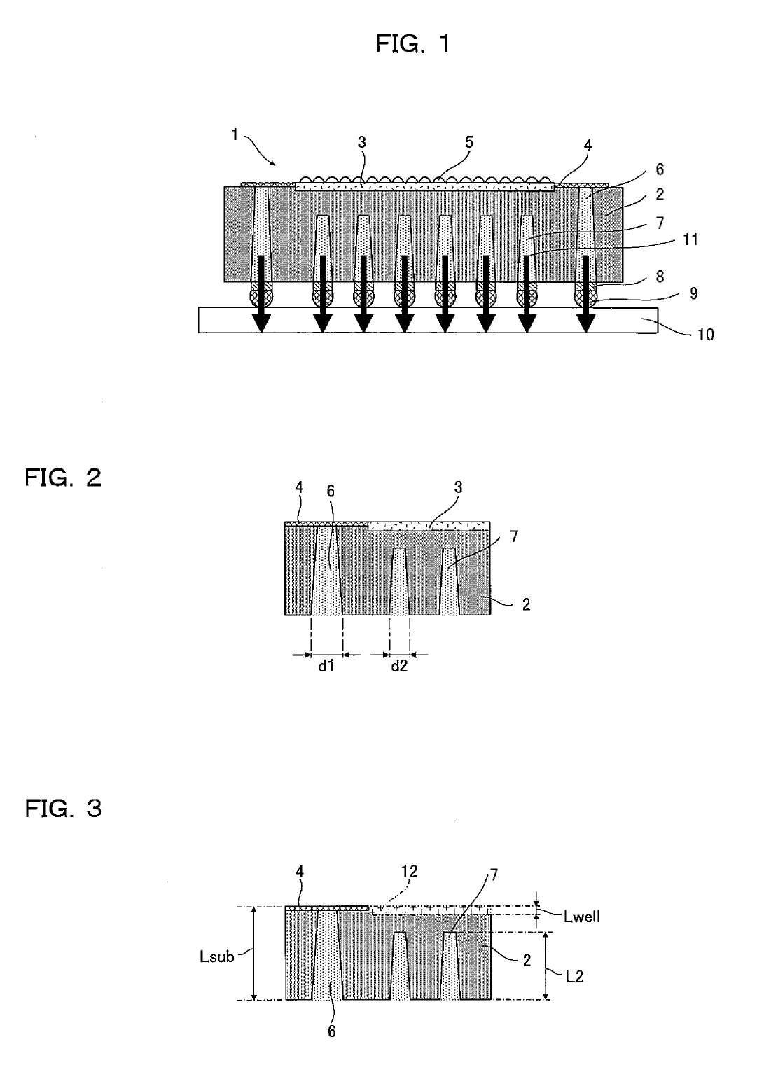

FIG. 1 is a sectional view showing a structural example of the solid-state image device according to the embodiment of the present invention. FIG. 1 shows the cross section of a CCD solid-state image device. In a solid-state image device 1, a light receiving part 3 and multiple top wiring layers 4 are formed on the top surface of a semiconductor substrate 2. In this configuration, the top surface of the semiconductor substrate 2 serves as a first surface and the underside of the semiconductor substrate 2 serves as a second surface. Further, the top wiring layers 4 act as front-side wires. The top wiring layers 4 are placed around the light receiving part 3 and are connected to the light receiving part 3. On the light receiving part 3, lenses 5 are provided to improve light collection efficiency.

On the top surface of the semiconductor substrate 2, elements including a horizontal CCD and an output amplifier are formed (not shown) which constitute a CCD solid-state image element. Further, a light transmissive member (not shown) is provided above the semiconductor substrate 2. In the case of a MOS solid-state image device, elements constituting a MOS solid-state image element, e.g., a circuit such as various scanning circuits, an output circuit, and a logic circuit are formed on the top surface of a semiconductor substrate in addition to a light receiving part and top wiring layers.

On the semiconductor substrate 2, a plurality of penetration electrodes 6 are formed. The penetration electrodes 6 penetrate the semiconductor substrate 2 from the underside to the top surface of the semiconductor substrate 2 and are connected to the top wiring layers 4. Further, non-through heat dissipation portions 7 are formed on the semiconductor substrate 2. The non-through heat dissipation portion 7 is made up of a non-through hole and a metal embedded in the non-through hole. The non-through hole has one open end on the underside of the semiconductor substrate 2, extends from the underside toward the top surface of the semiconductor substrate 2, and has the other end between the top surface and the underside of the semiconductor substrate 2.

On the underside of the semiconductor substrate 2, a plurality of bottom wiring layers 8 are formed. The ends of the penetration electrodes 6 and the non-through heat dissipation portions 7 on the underside of the semiconductor substrate 2 are connected to the bottom wiring layers 8. In this configuration, the bottom wiring layers 8 serve as underside wires. In the case of a solid-state image device of WLCSP, solder balls 9 are provided as external connection electrodes on the bottom wiring layers 8. The penetration electrodes 6 and the non-through heat dissipation portions 7 are connected to the solder balls 9 via the bottom wiring layers 8.

The solid-state image device 1 configured thus is mounted on a printed circuit board 10, so that heat from the solid-state image element formed on the semiconductor substrate 2 is dissipated to the printed circuit board 10 through heat dissipation paths 11. The heat dissipation paths 11 include paths from the non-through heat dissipation portions 7 to the printed circuit board 10 through the bottom wiring layers 8 and the solder balls 9 as well as paths from the penetration electrodes 6 to the printed circuit board 10 through the bottom wiring layers 8 and the solder balls 9. In the solid-state image device of the related art, heat is dissipated to the printed circuit board only from the penetration electrodes formed directly under the wiring layers placed around the light receiving part, whereas in the present embodiment, heat is dissipated also from the non-through heat dissipation portions 7 to the printed circuit board, improving heat dissipation as compared with the related art.

FIG. 2 shows the relationship between the end diameters of the penetration electrode 6 and the non-through heat dissipation portion 7 on the underside of the semiconductor substrate 2. In FIG. 2, reference character d1 denotes the end diameter of the penetration electrode 6 on the underside of the semiconductor substrate 2 and reference character d2 denotes the end diameter of the non-through heat dissipation portion 7 on the underside of the semiconductor substrate 2.

As shown in FIG. 2, the end diameter d2 of the non-through heat dissipation portion 7 is smaller than the end diameter d1 of the penetration electrode 6. This relationship is established in a first example of a method of manufacturing the solid-state image device according to the present embodiment. The first example will be described later.

The following will describe the depth of the non-through heat dissipation portion 7. FIG. 3 shows the positional relationship between the non-through heat dissipation portions 7 and a well. In FIG. 3, reference numeral 12 denotes the well formed on the surface (top surface) of the semiconductor substrate 2.

As shown in FIG. 3, it is necessary to prevent the non-through heat dissipation portions 7 from reaching the well 12 formed on the semiconductor substrate 2. In other words, the depth of the non-through heat dissipation portion 7 has to satisfy the following relationship:

L2<Lsub−Lwell

where Lsub is the thickness of the semiconductor substrate 2, Lwell is the depth of the well 12, and L2 is the depth of the non-through heat dissipation portion 7. This restriction is necessary because the non-through heat dissipation portions 7 reaching the well 12 may fluctuate the voltage of the well 12 and the fluctuations in voltage may adversely affect image characteristics.

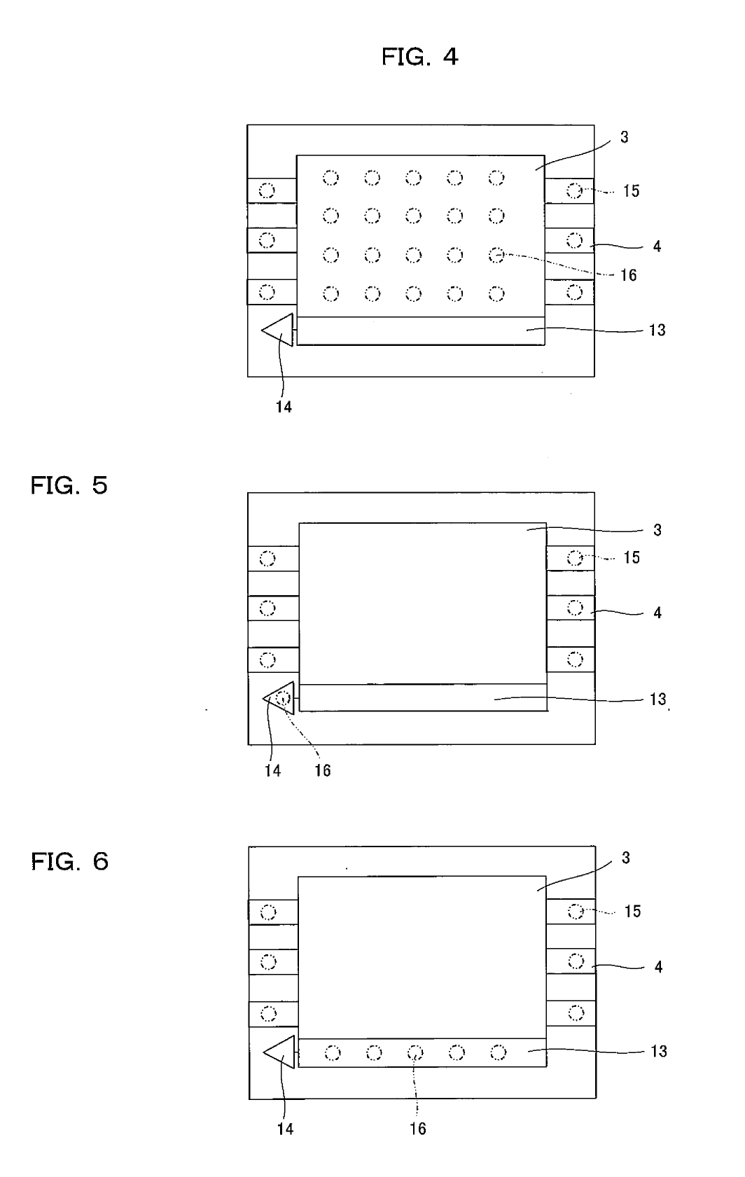

Referring to FIGS. 4 to 6, the following will describe the positions of the non-through heat dissipation portions 7 formed in the CCD solid-state image device. FIG. 4 is a top view showing the CCD solid-state image device according to the embodiment of the present invention. FIG. 4 shows an example of the positions of the non-through heat dissipation portions 7 formed in the CCD solid-state image device. FIGS. 5 and 6 are also top views showing the CCD solid-state image device according to the embodiment of the present invention. FIGS. 5 and 6 show other examples of the positions of the non-through heat dissipation portions 7 formed in the CCD solid-state image device. In FIGS. 4 to 6, reference numeral 13 denotes a horizontal CCD, reference numeral 14 denotes an output amplifier, reference numeral 15 denotes penetration electrode formation regions in which the penetration electrodes are formed, and reference numeral 16 denotes non-through heat dissipation portion formation regions in which the non-through heat dissipation portions 7 are formed.

As shown in FIG. 4, the ends of the non-through heat dissipation portions 7 near the top surface of the semiconductor substrate 2 are preferably placed directly under the light receiving part 3. This configuration can efficiently dissipate heat from beneath the light receiving part 3 in which heat is a direct cause of image degradation. Thus the temperature of the light receiving part 3 can be effectively reduced.

The non-through heat dissipation portions 7 may be formed near a portion having large power consumption, other than the light receiving part 3. For example, as shown in FIG. 5, the end of the non-through heat dissipation portion 7 near the top surface of the semiconductor substrate 2 may be placed directly under the output amplifier 14. Alternatively, as shown in FIG. 6, the ends of the non-through heat dissipation portions 7 near the top surface of the semiconductor substrate 2 may be placed directly under the horizontal CCD 13. This configuration has heat dissipation paths near a portion acting as a main heat source, achieving efficient heat dissipation.

As has been discussed, the non-through heat dissipation portions 7 are formed partially on or over the light receiving part 3, the horizontal CCD 13, and the output amplifier 14, achieving efficient heat dissipation.

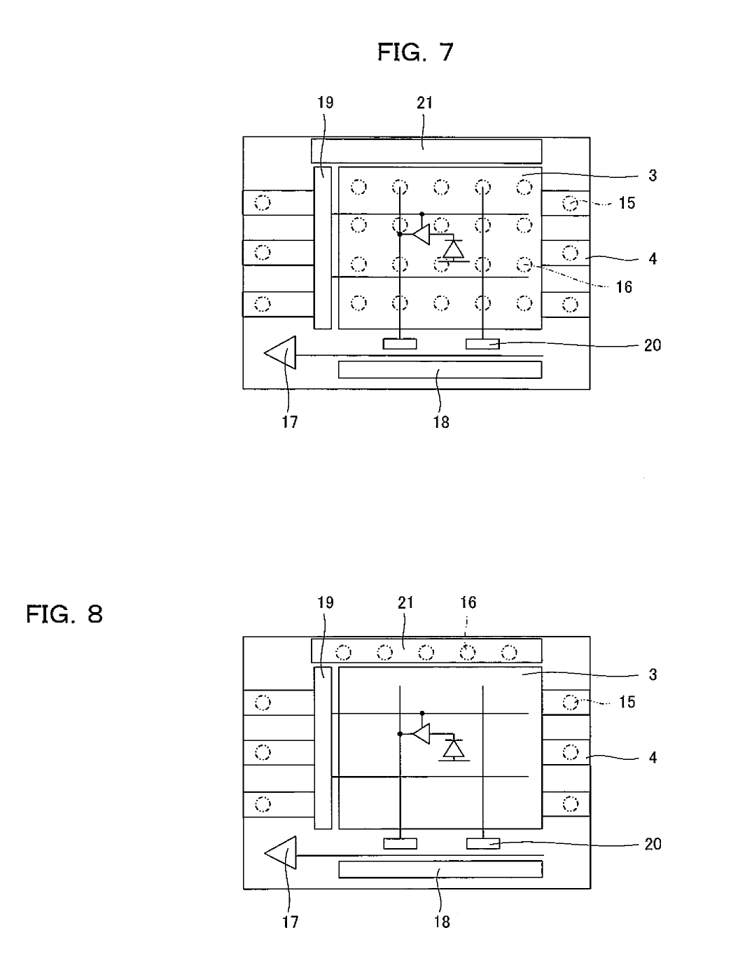

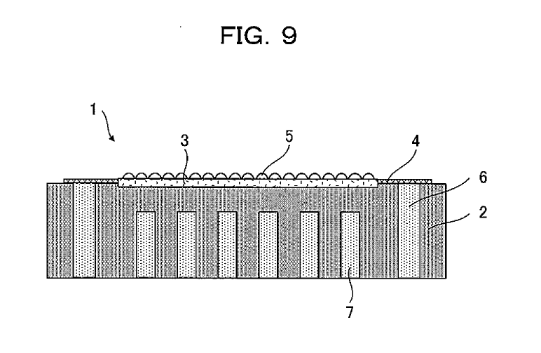

Referring to FIGS. 7 and 8, the following will describe the positions of non-through heat dissipation portions 7 formed in a MOS solid-state image device. FIG. 7 is a top view showing the MOS solid-state image device according the embodiment of the present invention. FIG. 7 shows an example of the positions of the non-through heat dissipation portions 7 formed in the MOS solid-state image device. FIG. 8 is a top view showing the MOS solid-state image device according to the embodiment of the present invention. FIG. 8 shows another example of the positions of the non-through heat dissipation portions 7 formed in the MOS solid-state image device. In FIGS. 7 and 8, reference numeral 17 denotes an output circuit, reference numeral 18 denotes a horizontal scanning circuit, reference numeral 19 denotes a vertical scanning circuit, reference numeral 20 denotes line circuits, and reference numeral 21 denotes a logic circuit. The logic circuit 21 includes a timing generator and an A/D converter.

In the MOS solid-state image device, as shown in FIG. 7, the ends of the non-through heat dissipation portions 7 near the top surface of the semiconductor substrate 2 are preferably placed directly under the light receiving part 3. Alternatively, as shown in FIG. 8, the ends of the non-through heat dissipation portions 7 near the top surface of the semiconductor substrate 2 are preferably placed directly under the logic circuit 21. With this configuration, heat is efficiently dissipated from beneath the light receiving part 3, in which heat is a direct cause of image degradation, or from beneath the logic circuit 21 that is a main heat source of the MOS solid-state image device. As a matter of course, the non-through heat dissipation portions 7 may be formed in the regions of the light receiving part 3 and the logic circuit 21.

As shown in FIGS. 4 to 8, the penetration electrode formation regions 15 are provided for the respective top wiring layers 4.

The following will describe the shape of the non-through heat dissipation portion. As shown in FIG. 1, the non-through heat dissipation portions 7 are tapered so as to decrease in diameter from the underside to the top surface of the semiconductor substrate 2. The non-through heat dissipation portions 7 are formed according to the first example of the method of manufacturing the solid-state image device according to the present embodiment. The first example will be described later.

As shown in FIG. 9, the non-through heat dissipation portions 7 may have a constant diameter. In this configuration, the non-through heat dissipation portions 7 are formed according to a second example of the method of manufacturing the solid-state image device according to the present embodiment. The second example will be described later. In this case, the non-through heat dissipation portions 7 may have any diameter.

The metal in the non-through heat dissipation portions 7 will be described below. Preferably, copper is used as the metal in the non-through heat dissipation portions 7. This is because copper has a high thermal conductivity and high heat dissipation is expected. The same effect as copper can be obtained by using other highly thermally conductive materials such as gold, silver, aluminum, tungsten, and a 42 alloy (Fe-42% Ni alloy) in the non-through heat dissipation portions.

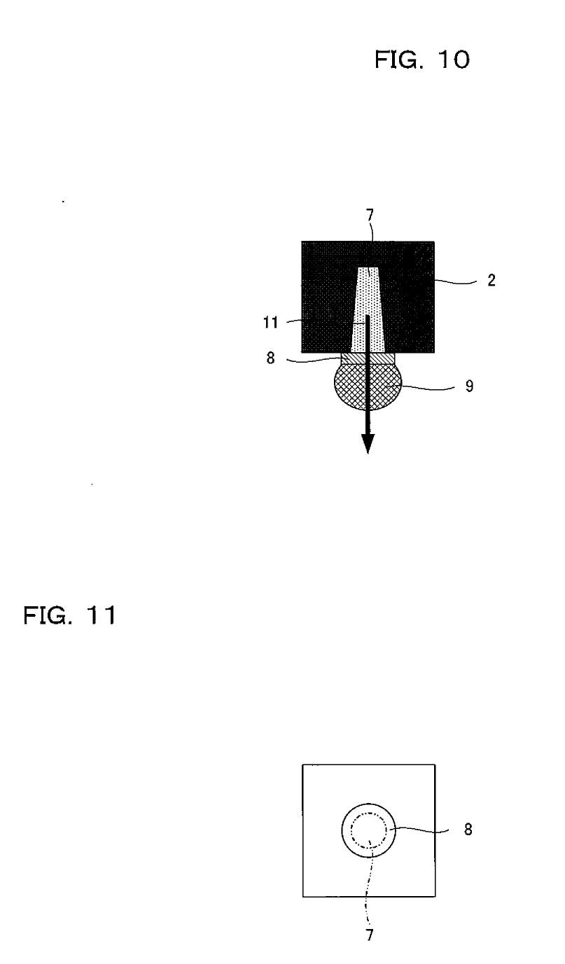

The following will describe the positional relationship between the non-through heat dissipation portion 7 and the solder ball 9. FIG. 10 is a sectional view for explaining an example of the positional relationship between the non-through heat dissipation portion 7 and the solder ball 9. FIG. 11 is a bottom view for explaining the example of the positional relationship between the non-through heat dissipation portion 7 and the solder ball 9.

As shown in FIGS. 10 and 11, the solder ball 9 may be provided directly under the end of the non-through heat dissipation portion 7 on the underside of the semiconductor substrate 2. With this configuration, the solder ball 9 connected to the non-through heat dissipation portion 7 via the bottom wiring layer 8 is close to the non-through heat dissipation portion 7, achieving more effective heat dissipation.

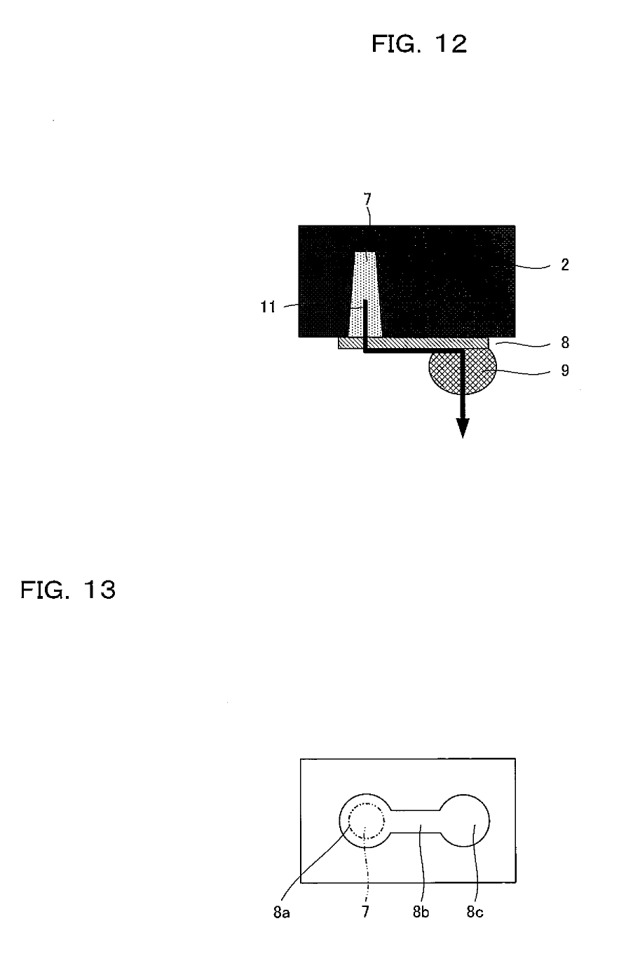

The following will describe another example of the positional relationship between the non-through heat dissipation portion 7 and the solder ball 9. FIG. 12 is a sectional view for explaining the other example of the positional relationship between the non-through heat dissipation portion 7 and the solder ball 9. FIG. 13 is a bottom view for explaining the other example of the positional relationship between the non-through heat dissipation portion 7 and the solder ball 9.

As shown in FIG. 12, the solder ball 9 may be provided with being separated away from beneath the end of the non-through heat dissipation portion 7 on the underside of the semiconductor substrate 2. In this case, as shown in FIG. 13, the bottom wiring layer 8 includes a portion 8a formed directly under the end of the non-through heat dissipation portion 7 on the underside of the semiconductor substrate 2, a portion 8c formed away from beneath the end of the non-through heat dissipation portion 7 on the underside of the semiconductor substrate 2, and a portion 8b connecting the portions 8a and 8c. The solder ball 9 is provided on the portion 8c of the bottom wiring layer 8.

With this configuration, it is not necessary to form the non-through heat dissipation portions 7 directly on the positions of the solder balls 9, easing restrictions on the positions of the non-through heat dissipation portions 7 relative to the layout of the solder balls 9. Further, it is not necessary to align the non-through heat dissipation portions 7 and the solder balls 9 with high accuracy, so that the solid-state image device can be more easily fabricated.

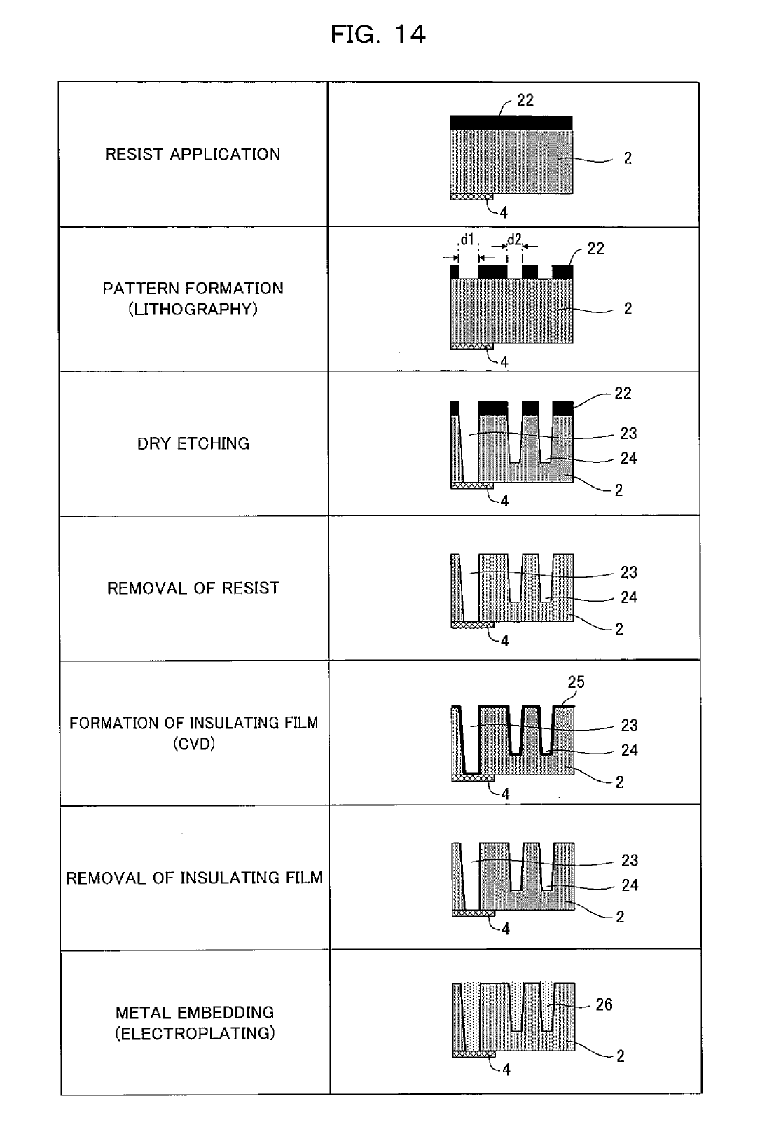

Referring to FIG. 14, the following will describe an example of the method of manufacturing the solid-state image device according to the present embodiment. FIG. 14 shows an example of the process of simultaneously forming the penetration electrodes and the non-through heat dissipation portions. The penetration electrodes and the non-through heat dissipation portions are formed after the solid-state image element including the light receiving part and the top wiring layers is formed on the top surface of the semiconductor substrate.

First, a photoresist 22 is applied to the underside of the semiconductor substrate 2. Next, the photoresist 22 is patterned with an opening diameter d1 and an opening diameter d2 by photolithography. In this case, the photoresist 22 is patterned such that the opening diameter d1 is larger than the opening diameter d2. Openings having the opening diameter d1 are formed at the positions of the penetration electrode formation regions and openings having the opening diameter d2 are formed at the positions of the non-through heat dissipation portion formation regions. Thus the method of manufacturing the solid-state image device forms a pattern in which the opening formed on the penetration electrode formation regions have a different opening diameter from the opening formed on the non-through heat dissipation portion formation regions.

Next, dry etching is performed on the underside of the semiconductor substrate 2 and holes are formed on the semiconductor substrate 2. The etching is stopped when the holes having the opening diameter d1 reach the top surface of the semiconductor substrate 2. Thus the holes having the opening diameter d2 become non-through holes.

At this point, a sedimentary gas is somewhat excessively added, so that the holes with the different opening diameters from each other are analogously tapered toward the top surface of the semiconductor substrate 2 in vertical section. Typically, as the sedimentary gas, perfluoro carbon (PFC) is used.

In typical dry etching, when deep holes are formed for openings, a sedimentary gas is added as a reactant gas. Then, the sedimentary gas dissociated by plasma is deposited as etching suppression films on the inner walls of the holes during the etching, thereby preventing an increase in the pore size of the holes. At this point, when the sedimentary gas is somewhat excessively added to prevent roughness, that is, unevenness on the inner walls of the holes, the inner walls of the holes are tapered.

In the dry etching, through holes 23 are formed in the penetration electrode formation regions and non-through holes 24 are formed in the non-through heat dissipation portion formation regions. To be specific, the through holes 23 penetrate the semiconductor substrate 2 from the underside to the top surface of the semiconductor substrate 2 and reach the top wiring layers 4. The non-through holes 24 have one open ends on the underside of the semiconductor substrate 2, extend from the underside toward the top surface of the semiconductor substrate 2, and have the other ends between the top surface and the underside of the semiconductor substrate 2.

Next, the patterned photoresist 22 is removed and then an insulating film 25 is formed on the underside of the semiconductor substrate 2 by, e.g., chemical vapor deposition (CVD). This processing forms the insulating film 25 on the inner surfaces of the through holes 23, the exposed surfaces of the top wiring layers 4 in the through holes 23, and the inner surfaces of the non-through holes 24.

After that, the insulating film 25 is removed from the exposed surfaces of the top wiring layers 4 in the through holes 23. Finally, a metal 26 is embedded in the through holes 23 and the non-through holes 24 by, e.g., electroplating.

In this case, the holes are formed on the semiconductor substrate by dry etching. As a matter of course, the holes may be formed by wet etching.

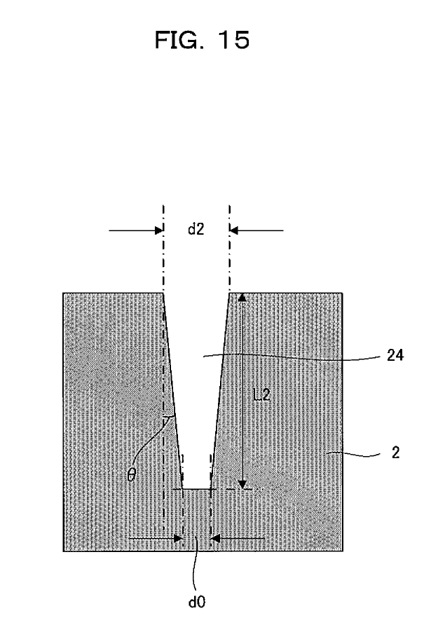

FIG. 15 shows the relationship between the opening diameter d2 of the non-through hole 24 and the taper angle of etching. In FIG. 15, reference character L2 denotes the depth of the non-through hole 24, reference character θ denotes the taper angle of etching, and reference character d0 denotes the end diameter of the non-through hole 24. When the end diameter is d0 at the stop of etching, the opening diameter d2 of the non-through hole 24 satisfies the following equation:

d2=d0+2×L×tan θ

Generally, θ is about 3° to 7°, d0 is several μm to several tens μm, and L is several hundreds μm. Thus it is expected that the non-through hole has a diameter of 20 μm to 150 μm.

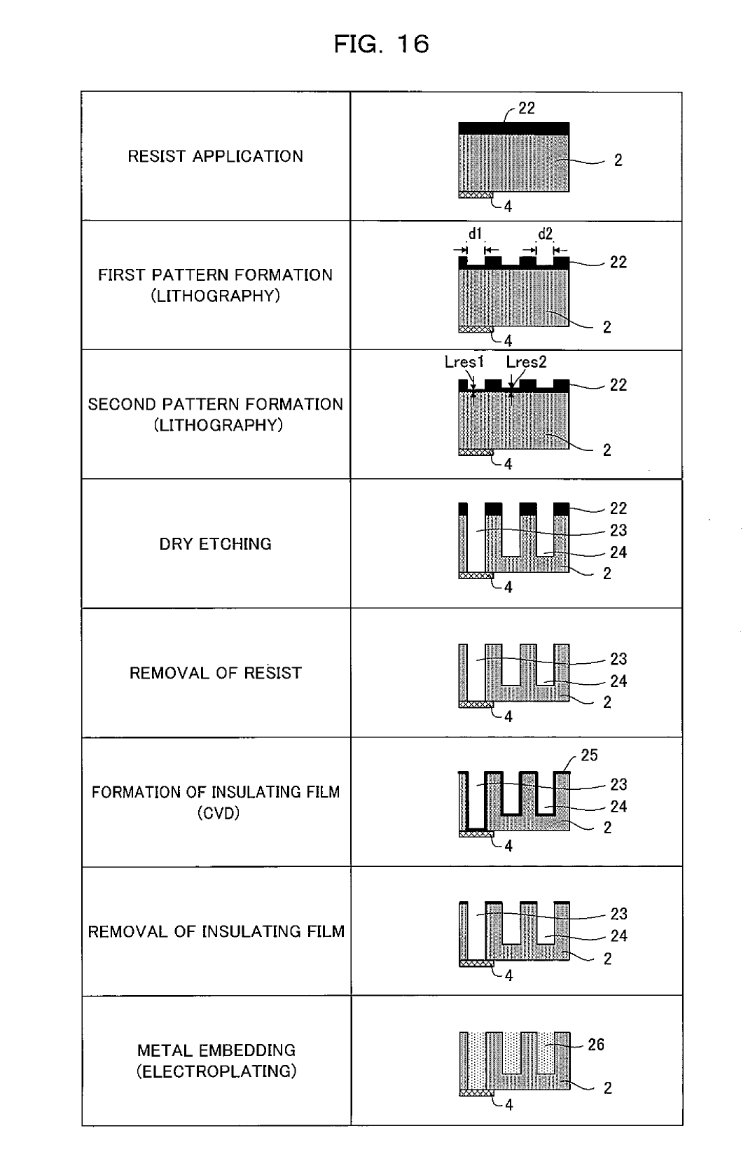

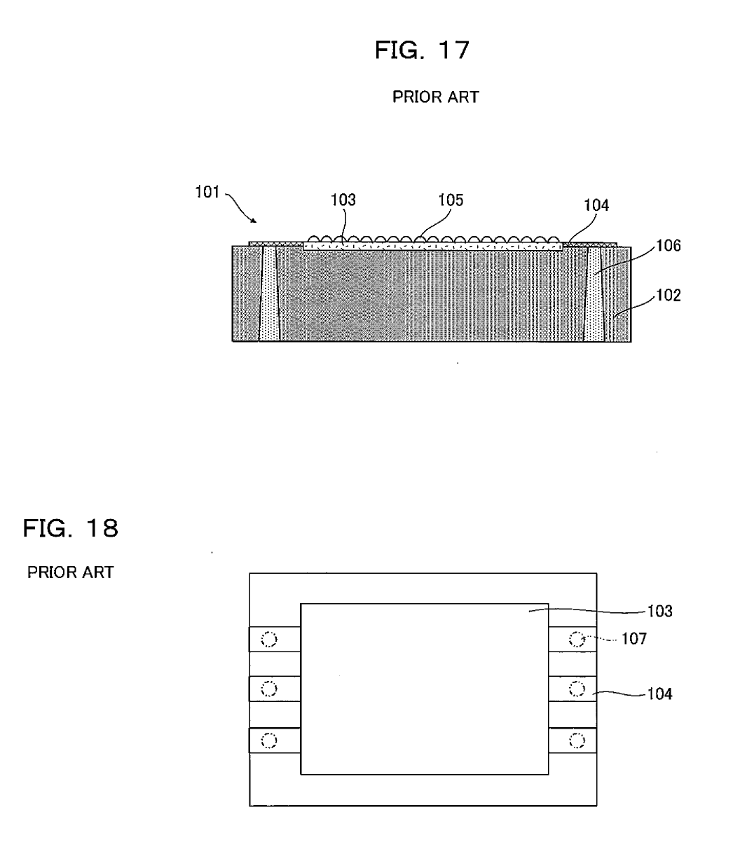

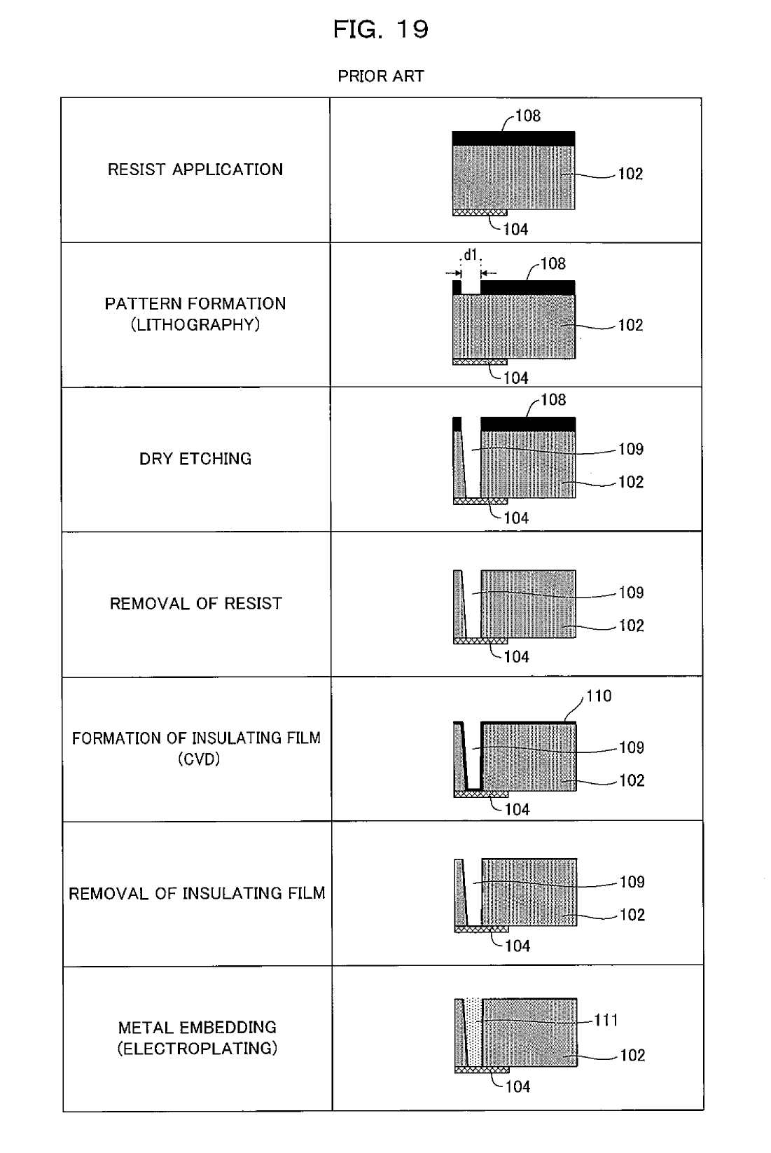

Referring to FIG. 16, the following will describe another example of the method of manufacturing the solid-state image device according to the present embodiment. FIG. 16 shows another example of the process of simultaneously forming the penetration electrodes and the non-through heat dissipation portions. The penetration electrodes and the non-through heat dissipation portions are formed after the solid-state image element including the light receiving part and the top wiring layers is formed on the top surface of the semiconductor substrate.

First, the photoresist 22 is applied to the underside of the semiconductor substrate 2. Next, the photoresist 22 is patterned with an opening diameter d1 and an opening diameter d2 by photolithography while leaving the bottoms of openings. In this configuration, openings having the opening diameter d1 are formed at the positions corresponding to the penetration electrode formation regions and openings having the opening diameter d2 are formed at the positions corresponding to the non-through heat dissipation portion formation regions. The method of manufacturing the solid-state image device does not depend on which is larger between the opening diameter of the penetration electrode formation region and the opening diameter of the non-through heat dissipation portion formation region.

Next, the photoresist is removed by photolithography from the bottoms of the openings formed at the positions of the penetration electrode formation regions, in a state in which masking is performed on the openings formed at the positions of the non-through heat dissipation portion formation regions. In this case, the following relationship is established:

Lres1<Lres2

where Lres1 is the resist thickness of a portion corresponding to the penetration electrode formation region, that is, the opening having the opening diameter d1, and Lres2 is the resist thickness of a portion corresponding to the non-through heat dissipation portion formation region, that is, the opening having the opening diameter d2. In other words, a pattern is formed such that the opening formed on the penetration electrode formation region has a different depth from the opening formed on the non-through heat dissipation portion formation region.

Next, dry etching is performed on the underside of the semiconductor substrate 2 and holes are formed on the semiconductor substrate 2. The etching is stopped when the holes having the opening diameter d1 reach the top surface of the semiconductor substrate 2. Thus the holes having the opening diameter d2 become non-through holes.

At this point, the flow rate of a sedimentary gas is reduced to lower the partial pressure of the sedimentary gas, so that the side walls of the holes can be straightened, that is, the holes can be controlled to vertical shapes. In other words, the through holes in the penetration electrode formation regions and the non-through holes in the non-through heat dissipation portion formation regions can be both straightened with a constant diameter in vertical section. When the side walls of the holes are straightened, the flow rate of the sedimentary gas is reduced by about 10% to 20% from the typical flow rate.

In the dry etching, the through holes 23 are formed in the penetration electrode formation regions and the non-through holes 24 are formed in the non-through heat dissipation portion formation regions. To be specific, the through holes 23 penetrate the semiconductor substrate 2 from the underside to the top surface of the semiconductor substrate 2 and reach the top wiring layers 4. The non-through holes 24 have one open ends on the underside of the semiconductor substrate 2, extend from the underside toward the top surface of the semiconductor substrate 2, and have the other ends between the top surface and the underside of the semiconductor substrate 2.

Next, the patterned photoresist 22 is removed and then the insulating film 25 is formed on the underside of the semiconductor substrate 2 by, e.g., chemical vapor deposition (CVD). This processing forms the insulating film 25 on the inner surfaces of the through holes 23, the exposed surfaces of the top wiring layers 4 in the through holes 23, and the inner surfaces of the non-through holes 24.

After that, the insulating film 25 is removed from the exposed surfaces of the top wiring layers 4 in the through holes 23. Finally, the metal 26 is embedded in the through holes 23 and the non-through holes 24 by, e.g., electroplating.

In this case, the holes are formed on the semiconductor substrate by dry etching. As a matter of course, the holes may be formed by wet etching.

As has been discussed, in the present embodiment, heat dissipation paths are formed from the non-through heat dissipation portions to the outside in addition to heat dissipation paths to the outside from the penetration electrodes formed directly under the top wiring layers placed around the light receiving part, thereby improving heat dissipation.

In this configuration, the non-through heat dissipation portions are not so deep as to reach the well formed on the semiconductor substrate. Thus it is possible to prevent the non-through heat dissipation portions from fluctuating the voltage of the well and adversely affecting an image.

Further, the non-through heat dissipation portions are formed directly under the light receiving part, thereby effectively reducing the temperature of the light receiving part in which heat is a direct cause of image degradation.

Moreover, the non-through heat dissipation portions are formed near a portion having large power consumption, so that the heat dissipation paths can be provided near the cause of heat and heat can be effectively dissipated.

Since copper is used in the non-through heat dissipation portions, heat can be more effectively dissipated through the highly thermally conductive metal.

In the case of a solid-state image device of WLCSP, non-through heat dissipation portions may be formed directly above or away from the positions of solder balls. When the non-through heat dissipation portions are formed directly above the positions of the solder balls, a distance between the non-through heat dissipation portions and the solder balls is shortened, thereby more effectively dissipating heat. When the non-through heat dissipation portions are formed away from the positions of the solder balls, it is not necessary to align the non-through heat dissipation portions and the solder balls with high accuracy, easing restrictions on the positions of the non-through heat dissipation portions relative to the layout of the solder balls. Thus the solid-state image device can be more easily fabricated.

### INDUSTRIAL APPLICABILITY

In the solid-state image device and the method of manufacturing the same according to the present invention, the heat dissipation of the solid-state image device can be improved. Further, the solid-state image device and the method of manufacturing the same according to the present invention are applicable to a CCD solid-state image device and a MOS solid-state image device. Therefore, the solid-state image device and the method of manufacturing the same according to the present invention are useful for equipment such as portable equipment, a digital still camera, and a video camera because such equipment requires size reduction and suppression of image degradation caused by heat generated in size reduction.

What is claimed is:

1. A solid-state image device comprising:
a semiconductor substrate having a first surface and a second surface opposed to the first surface;
a light receiving part formed on the first surface;
front-side wires formed around the light receiving part on the first surface;
penetration electrodes that penetrate the semiconductor substrate from the second surface to the first surface and are connected to the front-side wires; and
non-through heat dissipation portions each of which includes a non-through hole and a metal embedded in the non-through hole, the non-through hole having one open end on the second surface, extending from the second surface toward the first surface, and having an other end between the first surface and the second surface.

2. The solid-state image device according to claim 1, wherein the end of the non-through heat dissipation portion on the second surface is smaller in diameter than an end of the penetration electrode on the second surface.

3. The solid-state image device according to claim 1, wherein the non-through heat dissipation portions are not so deep as to reach a well formed on the semiconductor substrate.

4. The solid-state image device according to claim 1, comprising a CCD solid-state image element formed on the first surface.

5. The solid-state image device according to claim 4, wherein the ends of the non-through heat dissipation portions on the first surface are disposed directly under one of a light receiving part, an output amplifier, and a horizontal CCD of the CCD solid-state image element formed on the first surface.

6. The solid-state image device according to claim 1, comprising a MOS solid-state image element formed on the first surface.

7. The solid-state image device according to claim 6, wherein the ends of the non-through heat dissipation portions on the first surface are disposed directly under one of a light receiving part and a logic circuit of the MOS solid-state image element formed on the first surface.

8. The solid-state image device according to claim 1, wherein the non-through heat dissipation portions are tapered down from the second surface toward the first surface or have a constant diameter.

9. The solid-state image device according to claim 1, further comprising external connection electrodes on the second surface, the external connection electrodes being provided directly under the ends of the non-through heat dissipation portions on the second surface.

10. The solid-state image device according to claim 9, further comprising backside wires connected to the ends of the non-through heat dissipation portions on the second surface,
wherein the external connection electrodes are connected to the non-through heat dissipation portions via the backside wires.

11. The solid-state image device according to claim 1, further comprising:
backside wires connected to the ends of the non-through heat dissipation portions on the second surface; and
external connection electrodes connected to the backside wires,
wherein the external connection electrodes are separated from positions directly under the ends of the non-through heat dissipation portions on the second surface.

12. A method of manufacturing a solid-state image device, when penetration electrodes are formed on a semiconductor substrate that has a first surface and a second surface opposed to the first surface and includes wires on the first surface,
the method comprising the steps of:
forming a pattern on the second surface such that openings are formed on penetration electrode formation regions and non-through heat dissipation portion formation regions and the opening formed on the penetration electrode formation region and the opening formed on the non-through heat dissipation portion formation region have different opening diameters from each other;
forming through holes in the penetration electrode formation regions and non-through holes in the non-through heat dissipation portion formation regions, the through holes penetrating the semiconductor substrate from the second surface to the first surface and reaching the wires, the non-through holes having one open ends on the second surface, extending from the second surface toward the first surface, and having other ends between the first surface and the second surface;
removing the pattern;
forming an insulating film on inner surfaces of the through holes, exposed surfaces of the wires in the through holes, and inner surfaces of the non-through holes;
removing the insulating film on the exposed surfaces of the wires in the through holes; and
embedding a metal in the through holes and the non-through holes.

13. A method of manufacturing a solid-state image device, when penetration electrodes are formed on a semiconductor substrate that has a first surface and a second surface opposed to the first surface and includes wires on the first surface,
the method comprising the steps of:
forming a pattern on the second surface such that openings are formed on penetration electrode formation regions and non-through heat dissipation portion formation regions and the opening formed on the penetration electrode formation region has a different depth from the opening formed on the non-through heat dissipation portion formation region;
forming through holes in the penetration electrode formation regions and non-through holes in the non-through heat dissipation portion formation regions, the through holes penetrating the semiconductor substrate from the second surface to the first surface and reaching the wires, the non-through holes having one open ends on the second surface, extending from the second surface toward the first surface, and having other ends between the first surface and the second surface;
removing the pattern;
forming an insulating film on inner surfaces of the through holes, exposed surfaces of the wires in the through holes, and inner surfaces of the non-through holes;
removing the insulating film on the exposed surfaces of the wires in the through holes; and
embedding a metal in the through holes and the non-through holes.
